(19) United States
(12) Patent Application Publication
(10) Pub. No.: US 2018/0297836 A1
(43) Pub. Date: Oct. 18, 2018

(54) MEMS DEVICE PACKAGE AND METHOD FOR PACKAGING MEMS DEVICE

(71) Applicant: Shanghai Huahong Grace Semiconductor Manufacturing Corporation, Shanghai (CN)

(72) Inventor: WaiSoon Liew, Shanghai (CN)

(73) Assignee: Shanghai Huahong Grace Semiconductor Manufacturing Corporation, Shanghai (CN)

(21) Appl. No.: 15/828,816

(22) Filed: Dec. 1, 2017

(30) Foreign Application Priority Data
Apr. 14, 2017 (CN) 201710241902.8

(51) Int. Cl. B81B 7/00; B81C 1/00; H01L 31/0203

(52) U.S. Cl. CPC B81B 7/0035; B81B 7/0067; B81B 2201/0292; H01L 31/0203; B81C 1/00134

(57) ABSTRACT

A package for a MEMS device and a method for packaging a MEMS device are disclosed. The package includes a first die and a second die. The first die has a first central area and a first peripheral area surrounding the first central area, and the second die has a second central area and a second peripheral area surrounding the second central area. A first bond in the first peripheral area is bonded to a second bond in the second peripheral area so that a closed space is defined between the first central area and the second central area. Such a MEMS device package is airtight, and the second die can be easily fabricated without additional processing. Therefore, the MEMS device package disclosed in the present invention has good airtight performance and can be fabricated easily at low cost.

### CROSS-REFERENCES TO RELATED APPLICATIONS

This application claims the priority of Chinese patent application number 201710241902.8, filed on Apr. 14, 2017, the entire contents of which are incorporated herein by reference.

### TECHNICAL FIELD

The present invention relates to the field of semiconductor packaging technology and, in particular, to a packaging method for a micro-electro-mechanical system (MEMS) device.

### BACKGROUND

Micro-electro-mechanical system (MEMS) sensors are novel sensors fabricated using microelectronic and micro-mechanical machining techniques. Among the many advantages MEMS sensors have in comparison to traditional sensors, are its small size, light weight, low cost, low power consumption, high reliability, suitability for mass production and ease of integration.

As most MEMS devices, e.g., micro-bolometers which are used as infrared (IR) sensors; are usually required to operate in a hermetic environment, a conventional MEMS sensor packaging method that typically includes a cap which forms a closed-space environment. A through-silicon via (TSVs) is then fabricated in the cap in order to enable electrical connections and airtightness of the MEMS device. However, such conventional packaging techniques require additional fabrication of the cap, which raises a number of disadvantages such as high processing cost and complexity, as well as reduced airtightness and even less hermetic condition.

Therefore, in order to address these disadvantages, there is a need for a novel MEMS device package and its method thereof.

### SUMMARY OF THE INVENTION

It is an objective of the present invention to provide a package for a micro-electro-mechanical system (MEMS) device and its relevant method for the said MEMS device with the purpose to increase packaging airtightness and lower the cost.

To this end, the package according to the present invention includes:

a first die having a first central area and a first peripheral area surrounding the first central area, wherein the MEMS device is formed in the first central area, and wherein a first bond and a contact are formed in the first peripheral area, whilst the first bond includes at least a first bonding frame, and the contact located externally to the said first bonding frame;

a second die having a second central area and a second peripheral area surrounding the said second central area, wherein a second bond is formed in the second peripheral area, whilst the second bond includes at least a second bonding frame; resulting to the second bond frame bonded to the first bond frame such that a closed space is defined between the first central area and the second central area; and a connection structure for connecting the contact.

Optionally, in the package, the MEMS device may be an infrared (IR) sensor or an IR sensors array. The IR sensor or each IR sensor in the IR sensors array may include a micro-bridge and a photosensitive layer covering the micro-bridge.

Optionally, in the package, the central area of the second die may be made of a material transmissible to IR radiation.

Optionally, in the package, the material transmissible to IR radiation may be one selected from the group consisting of silicon, germanium, calcium fluoride and zinc sulfide.

Optionally, in the package, the first bond may be bonded to the second bond through eutectic bonding.

Optionally, in the package, the eutectic bonding may be accomplished by any material combination selected from the group consisting of Au—In, Cu—Sn, Au—Sn, Au—Ge, Au—Si and Si—Ge.

Optionally, in the package, the first bond may further include a first supporting bond disposed external to the first bonding frame.

Optionally, in the package, the second bond may further include a second supporting bond disposed external to the second bonding frame. Optionally, in the package, the second peripheral area may further include a cavity formed therein; the cavity penetrates the second die and is located between the second bonding frame and the second supporting bond.

Optionally, in the package, the connection structure may include a connecting frame, a connecting lead and a further contact, and the connecting lead may be connected to the further contact at one end and to the contact at the other end.

According to another aspect of the present invention, the invention also provides a method for packaging a MEMS device, that includes: providing a first die having a first central area and a first peripheral area surrounding the first central area, wherein the MEMS device is formed in the first central area, and wherein a first bond and a contact are formed in the first peripheral area, the first bond including at least a first bonding ring, the contact located external to the first bonding frame;

providing a second die having a second central area and a second peripheral area surrounding the second central area, wherein a second bond is formed in the second peripheral area, the second bond including at least a second bonding frame and corresponding to the first bond;

Bonding the first bond to the second bond so that a closed space is defined between the first central area and the second central area; and connecting the contact with a connection structure.

Optionally, in the method, the MEMS device may be an IR sensor or an IR sensors array.

Optionally, in the method, the step in which the first die is provided may include: forming a sacrificial layer on a central area of a first substrate; forming a micro-bridge on a sidewall of the sacrificial layer; forming a photosensitive layer covering both the micro-bridge and the sacrificial layer; removing the sacrificial layer so that the first substrate is connected to the photosensitive layer via the micro-bridge; and forming a first bond and a contact in a peripheral area of the first substrate.

Optionally, in the method, IR radiation may be able to transmit through the second central area of the second die.

Optionally, in the method, the first bond may be bonded to the second bond through eutectic bonding.

Optionally, in the method, the first bond may further include a first supporting bond disposed external to the first bonding frame.

Optionally, in the method, the second bond may further include a second supporting bond disposed external to the second bonding frame.

Optionally, in the method, the step in which the second die is provided may further include forming a cavity in the second peripheral area so that the cavity penetrates the second die and is located between the second bonding frame and the second supporting bond.

Optionally, in the method, in the step in which the contact is connected with the connection structure, the connection structure may include a connecting frame, a connecting lead and a further contact, the connecting lead is connected to the further contact at one end and to the contact at the other end.

The present invention provides the following benefits over the prior art.

The MEMS device package includes the first die and the second die. The first die has the first central area and the first peripheral area surrounding the first central area, and the second die has the second central area and the second peripheral area surrounding the second central area. The first bond in the first peripheral area is bonded to the second bond in the second peripheral area so that a closed-space is defined between the first central area and the second central area in which the MEMS device is formed. Such a MEMS device package is airtight, and the second die can be easily fabricated without additional processing. Therefore, the MEMS device package has good airtight performance and can be fabricated easily at low cost.

Moreover, the method not only provides a more airtight package but also a window transparent to IR radiation for the IR sensor or the IR sensors array. According to the present invention, the second central area of the second die can be made of any of the commonly-used IR-transmissible materials, i.e., silicon, germanium, calcium fluoride and zinc sulfide. Compared to the prior art, the inventive packaging method can be more easily implemented at lower cost without requiring additional processes in forming the window.

### BRIEF DESCRIPTION OF THE DRAWINGS

FIGS. 1 to 4 are structural schematics illustrating respective steps of a conventional method (prior art) for packaging an infrared (IR) sensor.

FIG. 5 is a flowchart graphically illustrating a method for packaging a micro-electro-mechanical system (MEMS) device in accordance with embodiments of the present invention.

FIGS. 6 to 11 are schematic cross-sectional views illustrating steps of the method for packaging a MEMS device in accordance with embodiments of the present invention.

FIG. 12 is a perspective view of a MEMS device package in accordance with embodiments of the present invention.

### DETAILED DESCRIPTION

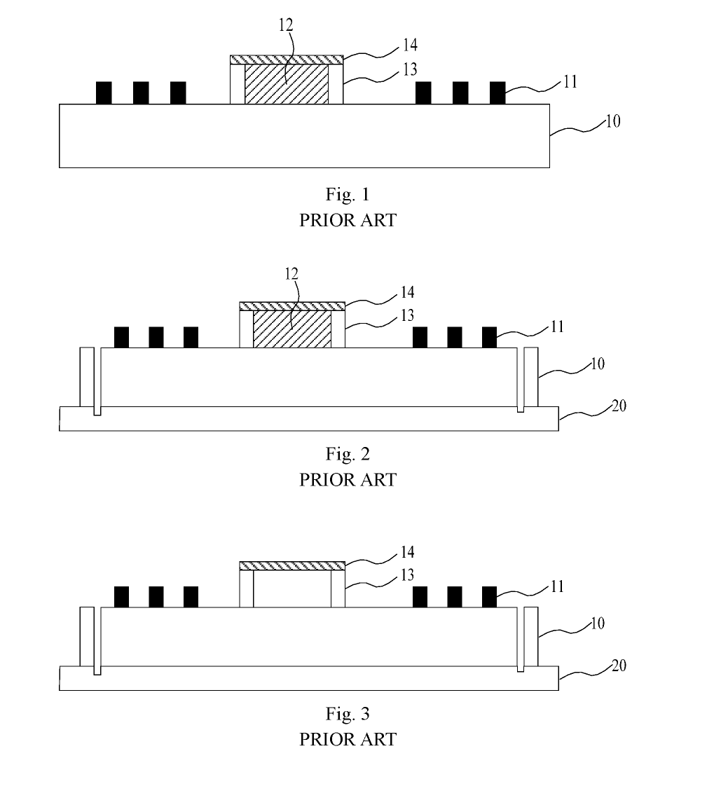

FIGS. 1 to 4 are structural schematics illustrating respective steps of a well-known conventional method for packaging an infrared (IR) sensor. As shown in FIG. 1, a first substrate 10 containing a circuit of the sensor is first provided, and a number of first contacts 11 for electrically connecting the circuit to external circuits are formed in a first surface of the first substrate 10. A sacrificial layer 12, which may be silicon oxide, amorphous silicon, photosensitive polyimide or another commonly-used material, is additionally formed on the first surface of the first substrate 10. A micro-bridge 13 is then formed over a sidewall of the sacrificial layer 12, followed by the formation of a photosensitive layer 14 which covers both the sacrificial layer 12 and the micro-bridge 13. The resulting structure may be collectively referred to as a die to be packaged. After that, the die is subjected to a cutting process in which the die (specifically, a second surface of the first substrate 10) is bonded to a blue tape 20 and cut, resulting in a structure as shown in FIG. 2. Subsequently, the sacrificial layer 12 is removed, resulting in a structure as shown in FIG. 3. Depending on its material, different techniques may be used to remove the sacrificial layer 12. For example, silicon oxide is often removed by gaseous hydrofluoric acid, amorphous silicon by xenon difluoride (XeF₂), and photosensitive polyimide by oxygen plasma. It is to be noted that, in this well-known packaging method, the sacrificial layer 12 is removed after the die cutting process and due to this step, a small amount of debris may be produced during the cutting process and potentially present around the photosensitive layer 14 and thus impair the performance of the IR sensor during fabrication when the sacrificial layer 12 is removed. After that, the die is also subjected to a process, whereby the blue tape 20 is peeled-off

Afterward, a cap for encapsulating the die is fabricated. As shown in FIG. 4, the cap is formed of a metal frame 30 and a particular window 31, which together define a closed space A. The window 31 allows transmission of IR radiation and its position and dimensional features are in correspondence with the photosensitive layer 14. The cap further includes a through-silicon via (TSV) 32 and a metal lead 33. The TSV 32 is fixed to the metal frame 30, and the metal lead 33 is connected to the TSV 32 at one end and to the first contact 11 at the other end, thereby connecting the IR sensor to external circuits. The completed package is as shown in FIG. 4.

From the description above, it is shown that the conventional packaging method involves the formation of the cap and the particular window 31. Furthermore, the sacrificial layer 12 is removed after the cutting process. Thus, such packaging method involves high process complexity, non-guarantee airtightness, higher cost and other potential problems.

Based on these findings, the inventors have conducted intensive research and propose a MEMS device package that includes:

a first die having a first central area and a first peripheral area surrounding the first central area, wherein the MEMS device is formed in the first central area, and wherein a first bond and a first contact are formed in the first peripheral area, the first bond including at least a first bonding frame, the first contact located external to the first bonding frame;

a second die having a second central area and a second peripheral area surrounding the second central area, wherein a second bond is formed in the second peripheral area, the second bond including at least a second bonding frame, the second bond bonded to the first bond so as to define a closed space between the first central area and the second central area; and

a connection structure connecting the first contact.

According to another aspect of the present invention, the inventors further propose a method for packaging a MEMS device. The method includes:

providing a first die having a first central area and a first peripheral area surrounding the first central area, wherein the MEMS device is formed in the first central area, and wherein a first bond and a first contact are formed in the first peripheral area, the first bond including at least a first bonding frame, the first contact located external to the first bonding frame;

providing a second die having a second central area and a second peripheral area surrounding the second central area, wherein a second bond is formed in the second peripheral area, the second bond including at least a second bonding frame, the second bond in correspondence with the first bond;

bonding the first bond to the second bond such that a closed space is defined between the first central area and the second central area; and

connecting the first contact with a connection structure.

The proposed MEMS device package includes the first die and the second die. The first die has the first central area and the first peripheral area surrounding the first central area, and the second die has the second central area and the second peripheral area surrounding the second central area. The first bond in the first peripheral area and the second bond in the second peripheral area are bonded together so that the closed space is defined between the first central area and the second central area, in which the MEMS device in the first die is arranged. Such a MEMS device package is airtight, and the second die can be fabricated in a simple way without additional processing. Therefore, the proposed MEMS device package can provide good airtightness and can be easily made at low cost.

The proposed MEMS device package and packaging method will be described in greater detail below with reference to the accompanying flowcharts and schematics, which present preferred embodiments of the invention. It is to be appreciated that those skilled in the art can make changes to the invention disclosed herein while still obtaining the beneficial results thereof. Therefore, the following description shall be construed as being intended to be widely known by those skilled in the art rather than as limiting the invention.

In the following paragraphs, the present invention will be described in greater detail by way of example with reference to the accompanying drawings. Features and advantages of the invention will be more apparent from the following detailed description, and from the appended claims. Note that the figures are provided in a very simplified form not necessarily presented to scale, with the only intention of facilitating convenience and clarity in explaining the embodiments.

For the sake of clarity, the following embodiments of the proposed MEMS device package and packaging method are described in the context of packaging of an IR sensor or an IR sensors array. However, it will be appreciated that the present invention is not limited to the following embodiments and that all modifications obtained by those of ordinary skill in the art based on conventional techniques are also embraced in the spirit of the invention.

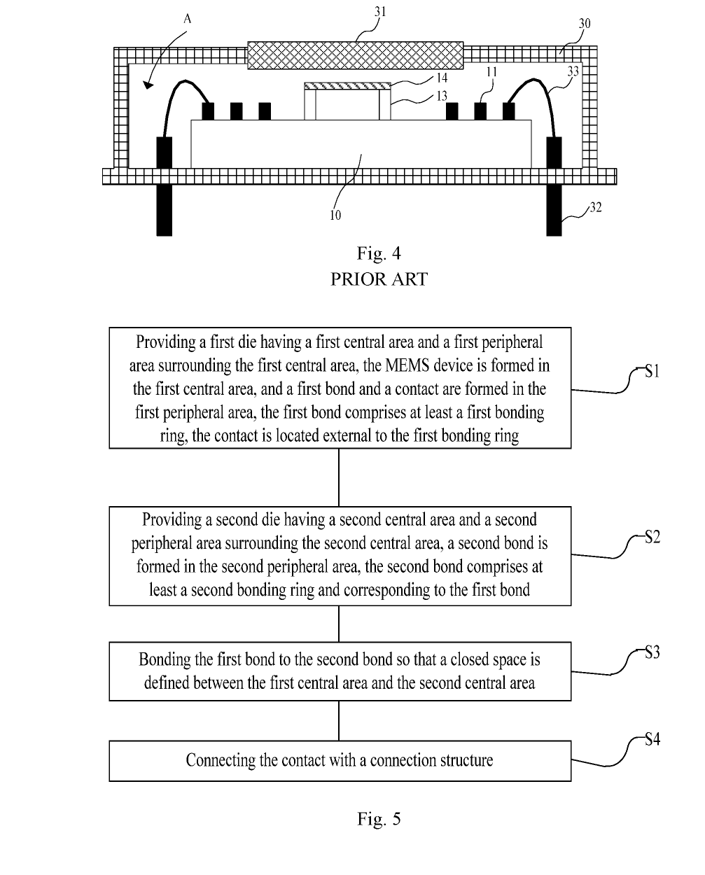

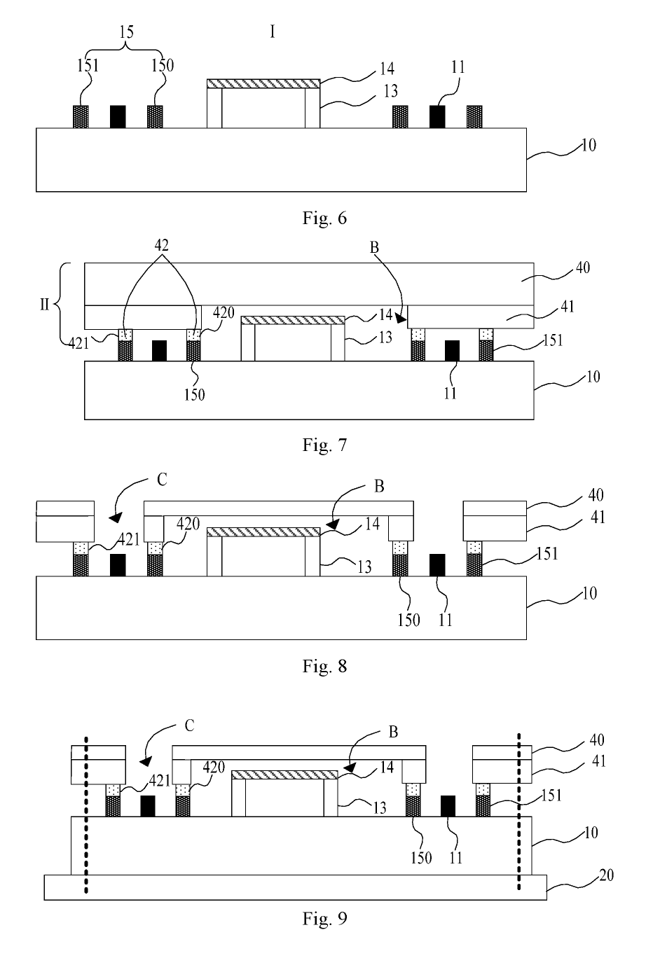

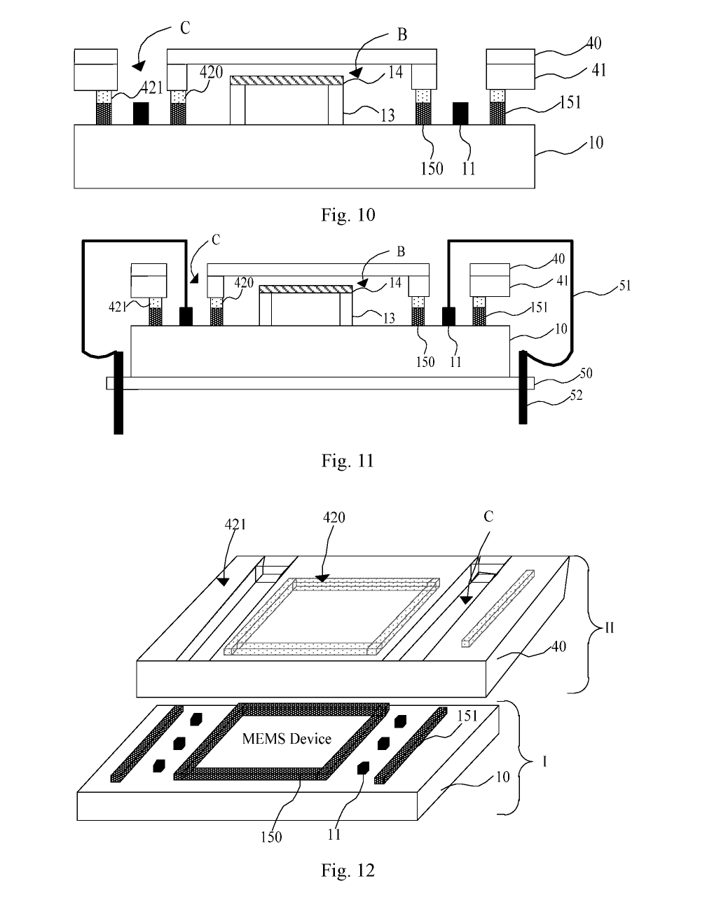

FIG. 5 is a flowchart graphically illustrating a method for packaging a MEMS device in accordance with embodiments of the present invention. FIGS. 6 to 11 are schematic cross-sectional views illustrating steps of a method for packaging a MEMS device in accordance with embodiments of the present invention. FIG. 12 is a perspective view of a MEMS device package in accordance with embodiments of the present invention.

As shown in FIG. 5, in step S1, a first die is provided. The first die has a first central area and a first peripheral area surrounding the first central area. The MEMS device is formed in the first central area, and a first bond and a first contact are formed in the first peripheral area. The first bond includes at least a first bonding frame, and the first contact is located external to the first bonding frame. As shown in FIG. 6, in which identical numerals indicate the same elements as FIG. 1, the photosensitive layer 14 and the micro-bridge 13 are formed in the central area of the first substrate 10 (i.e., the MEMS device (IR sensor or IR sensors array) is formed in the first central area of the first die I), with the first bond 15 being additionally formed in the peripheral area of the first substrate 10 (i.e., the first bond 15 is formed in the first peripheral area that surrounds the first central area), with the first bond 15 including at least the first bonding frame 150, and with the first contacts 11 being located external to the first bonding frame 150 (in this embodiment, each of the first contact 11 is a structure resulting from a contact hole filled with a metal). Preferably, in order for the MEMS device to be better packaged, in this embodiment, the first bond 15 further includes a first supporting bond 151 located external to the first bonding frame 150 (note that since the first bonding frame 150 and the first supporting bond 151 are formed with the same material, they are shown by the same pattern in the figure shown). Optically, the first supporting bond 151 may be bars (as in the case of this embodiment as shown in FIG. 12), a ring or the like and the present invention is not limited in this regard. In addition, in the method for packaging the IR sensor or the IR sensors array according to this embodiment, the first die I of FIG. 6 differs from the die to be packaged of FIG. 1 in that the sacrificial layer 12 has been removed prior to the subsequent cutting process. That is, the sacrificial layer 12 has been removed from the first die I using an appropriate technique.

Thereafter, step S2 is performed in which a second die is provided. The second die has a second central area and a second peripheral area surrounding the second central area. A second bond is formed in the second peripheral area. The second bond includes at least a second bonding frame. The second bond is provided in correspondence with the first bond. In particular, the formation of the second die may include the following steps. As shown in FIG. 7, a second substrate 40 is provided. In this embodiment, the second substrate 40 (and hence the second central area of the second die II) is transparent to IR radiation. Materials from which the second substrate 40 is fabricated may include, but not limited to, any of silicon, germanium, calcium fluoride and zinc sulfide. After that, a dielectric layer 41 may generally be formed on the peripheral area of the first surface of the second substrate 40. The dielectric layer 41 may be silicon oxide. The second bond 42 may be formed on the dielectric layer 41 (i.e., on the second peripheral area of the second die II that surrounds the second central area). The second bond 42 includes at least a second bonding frame 420. Preferably, in this embodiment, in order to be structurally in correspondence with the first bond 15, the second bond 42 may also include a second supporting bond 421 located external to the second bonding frame 420. Similarly, the second supporting bond 421 may also be bars or a ring. The second die II may be simply fabricated by a conventional semiconductor process.

In step S3, the first bond is bounded to the second bond so that a closed space is defined between the first central area and the second central area. As shown in FIG. 7, the first bond 15 and the second bond 42 may preferably be eutectically bonded together using any combination selected from Au—In, Cu—Sn, Au—Sn, Au—Ge, Au—Si and Si—Ge. In semiconductor processes, the eutectic bonding is usually performed at a temperature lower than 450° C. Depending on the eutectic materials used, the ratio between the materials and the temperature at the eutectic bonding is carried out may vary, and the present invention is not particularly limited in this regard. As a result, the closed space B is formed between the first central area and the second central area, and the eutectic bonding allows better sealing.

In step S4, the first contacts are connected using a connection structure. That is, the IR sensor or each IR sensor in the IR sensors array (i.e., the MEMS device in the first central area of the first die I) is electrically connected to external circuits via the first contacts 11. Preferably, the connection structure includes at least a connecting lead. For example, if the first contacts 11 are exposed, a connection may be made between the first contacts 11 and the connecting lead immediately after the cutting process. However, in this embodiment, in order to achieve better packaging, the first contacts 11 are formed between the first bonding frame 150 and the first supporting bond 151. Therefore, the method may further include the following processes prior to step S4.

As shown in FIG. 8, the peripheral area of the second surface of the second substrate 40 is etched so that a cavity C is formed in which the first contacts 11 are exposed (i.e., the cavity C is formed between the second bonding frame 420 and the second supporting bond 421). Apparently, the cavity C penetrates both the second substrate 40 and the dielectric layer 41 and may be generally formed by removing part of each of the second substrate 40 and the dielectric layer 41 by a deep reactive ion etching (DRIE) process. It is a matter of course that the etching of the second substrate 40 may be preceded by a chemical mechanical planarization (CMP) process on the second substrate 40. This is known to one of ordinary skill in the art and will not be described herein for clarity.

Next, as shown in FIGS. 9 and 10, the resulting structure as shown in FIG. 8 is subjected to a cutting process (along the dotted lines of FIG. 9, and the cutting process is followed by removal of the blue tape 20, resulting in the structure as shown in FIG. 10). In this embodiment, since the closed space B is formed prior to the cutting process, the removal of the sacrificial layer 12 precedes the cutting process and the performance of the device being fabricated will not be affect. Herein, the only change lies in the order of the cutting process rather than the process itself, thus the description of the cutting process will be not repeated.

The exposed first contact of the IR sensor (i.e., the MEMS device) is then electrically connected to external circuits by the connection structure. Preferably, as shown in FIG. 11, the connection structure may include a connecting frame 50, a connecting lead 51 and a second contact 52 connecting one end of the connecting lead 51 (in this embodiment, the second contact 52 is a structure resulting from a through hole filled with a metal). The second contact 52 is fixed to the connecting frame 50, and the connecting frame 50 is mounted on the second surface of the first substrate 10. The other end of the connecting lead 51 is connected to the first contact 11. With this done, the IR sensor package is completed (as shown in the cross-sectional view of FIG. 11 and the perspective view of FIG. 12 in which the connection structure is omitted).

The IR sensor package includes: the first die I having the first central area and the first peripheral area surrounding the first central area, wherein the MEMS device (IR sensor) is formed in the first central area, and wherein the first bond 15 and the first contacts 11 are formed in the first peripheral area, the first bond 15 including the first bonding frame 150 and the first supporting bond 151 located external to the first bonding frame 150, the first contacts 11 formed between the first bonding frame 150 and the first supporting bond 151;

the second die II having the second central area and the second peripheral area surrounding the second central area, wherein the second bond 42 is formed in the second peripheral area and includes the second bonding frame 420 and the second supporting bond 421, and wherein the second peripheral area includes the cavity C that penetrates the second die II and is located between the second bonding frame 420 and the second supporting bond 421, the cavity C configured to allow external connection of the first contacts 11; and

the connection structure, including the connecting frame 50, the connecting lead 51 and the second contact 52 connecting one end of the connecting lead 51, wherein the second contact 52 is fixed to the connecting frame 50 which is, in turn, mounted on the second surface of the first die I.

The IR sensor packaging methods according to the above embodiments are simple and allow low production cost, and the resulting IR sensor packages are airtight, enabling the IR sensor to be used in a wider range of applications.

In summary, the proposed MEMS device package includes the first die and the second die. The first die has the first central area and the first peripheral area surrounding the first central area, while the second die has the second central area and the second peripheral area surrounding the second central area. The first bond in the first peripheral area is bonded to the second bond in the second peripheral area so that the closed space is defined between the first central area and the second central area in which the MEMS device is disposed. Such a MEMS device package is airtight, and the second die can be easily fabricated without additional processing. Therefore, the proposed MEMS device package has good airtight performance and can be fabricated easily at low cost.

Additionally, the proposed method can provide not only a more airtight package but also a window transparent to IR radiation for the IR sensor. According to the present invention, the second central area of the second die can be made of any of the commonly-used IR-transmissible materials, i.e., silicon, germanium, calcium fluoride and zinc sulfide. Compared to the prior art, the proposed packaging method can be more easily implemented at lower cost whilst not requiring additional processes in forming the window.

It is apparent that those skilled in the art can make various changes and modifications without departing from the spirit and scope of the invention. Accordingly, it is intended that the present invention also embraces such changes and modifications if they fall within the scope of the appended claims and the equivalents thereof.

What is claimed is:

1. A package for a MEMS device, comprising:
a first die having a first central area and a first peripheral area surrounding the first central area, wherein the MEMS device is formed in the first central area, and wherein a first bond and a contact are formed in the first peripheral area, the first bond comprising at least a first bonding frame, the contact located external to the first bonding frame;
a second die having a second central area and a second peripheral area surrounding the second central area, wherein a second bond is formed in the second peripheral area, the second bond comprising at least a second bonding frame, the second bond being able to be bonded to the first bond such that a closed space is defined between the first central area and the second central area; and
a connection structure for connecting the contact.

2. The package according to claim 1, wherein the MEMS device is an infrared sensor or an infrared sensors array.

3. The package according to claim 2, wherein the infrared sensor or each infrared sensor in the infrared sensors array comprises a micro-bridge and a photosensitive layer covering the micro-bridge.

4. The package according to claim 3, wherein the second central area of the second die is made of a material transmissible to infrared radiation.

5. The package according to claim 4, wherein the material transmissible to infrared radiation is one selected from the group consisting of silicon, germanium, calcium fluoride and zinc sulfide.

6. The package according to claim 1, wherein the first bond is able to be bonded to the second bond through eutectic bonding.

7. The package according to claim 6, wherein the eutectic bonding is accomplished by any material combination selected from the group consisting of Au—In, Cu—Sn, Au—Sn, Au—Ge, Au—Si and Si—Ge.

8. The package according to claim 1, wherein the first bond further comprises a first supporting bond disposed external to the first bonding frame.

9. The package according to claim 8, wherein the second bond further comprises a second supporting bond disposed external to the second bonding frame.

10. The package according to claim 9, wherein the second peripheral area further comprises a cavity formed therein, the cavity penetrating the second die and located between the second bonding frame-and the second supporting bond.

11. The package according to claim 1, wherein the connection structure comprises a connecting frame, a connecting lead and a further contact, the connecting lead having a first end connected to the further contact and a second end connected to the contact.

12. A method for packaging a MEMS device, comprising:
providing a first die having a first central area and a first peripheral area surrounding the first central area, wherein the MEMS device is formed in the first central area, and wherein a first bond and a contact are formed in the first peripheral area, the first bond comprising at least a first bonding frame, the contact located external to the first bonding frame;
providing a second die having a second central area and a second peripheral area surrounding the second central area, wherein a second bond is formed in the second peripheral area, the second bond comprising at least a second bonding frame and corresponding to the first bond;
bonding the first bond to the second bond so that a closed space is defined between the first central area and the second central area; and
connecting the contact with a connection structure.

13. The method according to claim 12, wherein the MEMS device is an infrared sensor or an infrared sensors array.

14. The method according to claim 12, wherein providing a first die comprises:
forming a sacrificial layer on a central area of a first substrate;
forming a micro-bridge on a sidewall of the sacrificial layer;
forming a photosensitive layer covering both the micro-bridge and the sacrificial layer;
removing the sacrificial layer so that the first substrate is connected to the photosensitive layer via the micro-bridge; and
forming a first bond and a contact in a peripheral area of the first substrate.

15. The method according to claim 14, wherein infrared radiation is able to transmit through the second central area of the second die.

16. The method according to claim 12, wherein the first bond is bonded to the second bond through eutectic bonding.

17. The method according to claim 12, wherein the first bond further comprises a first supporting bond disposed external to the first bonding frame.

18. The method according to claim 17, wherein the second bond further comprises a second supporting bond disposed external to the second bonding frame.

19. The method according to claim 18, wherein providing a second die further comprises forming a cavity in the second peripheral area, the cavity penetrating the second die and located between the second bonding frame and the second supporting bond.

20. The method according to claim 12, wherein the connection structure comprises a connecting frame, a connecting lead and a further contact, the connecting lead having a first end connected to the further contact and having a second end connected to the contact.
